(19) United States
(12) Patent Application Publication
(10) Pub. No.: US 2007/0241796 A1
(43) Pub. Date: Oct. 18, 2007

(54) D-TYPE STATIC LATCH FOR HIGH FREQUENCY CIRCUIT

(75) Inventor: Mathilde Sie, Toulouse (FR)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignee: STMICROELECTRONICS SA, MONTROUGE (FR)

(21) Appl. No.: 11/733,330

(22) Filed: Apr. 10, 2007

(30) Foreign Application Priority Data
Apr. 10, 2006 (FR) 06 03137

(51) Int. Cl. H03K 23/00

(52) U.S. Cl. 327/115; 327/218

(57) ABSTRACT

A D-type static latch circuit is provided that includes first and second circuits connected between a first reference potential and a second reference potential, with the first circuit comprising a first transistor, a second transistor and a third transistor connected in series, and the second circuit comprising a fourth transistor, a fifth transistor and a sixth transistor connected in series. The latch circuit also includes a third circuit comprising a seventh transistor and a eighth transistor connected in series between a junction of the second and third transistors and a junction of the fifth and sixth transistors, a first data input connected to the gates of the third and seventh transistors, a second inverse data input connected to the gates of the sixth and eighth transistors, a third clock input connected to the gates of the second and fifth transistors, a first output connected to a junction of the first transistor and the second transistor, and a second output connected to a junction of the fourth transistor and the fifth transistor.

### CROSS-REFERENCE TO RELATED APPLICATIONS

This application is based upon and claims priority from prior French Patent Application No. 06 03137, filed Apr. 10, 2006, the entire disclosure of which is herein incorporated by reference.

### FIELD OF THE INVENTION

The present invention relates to the field of electronic circuits, and more particularly to a D-type static latch circuit.

### BACKGROUND OF THE INVENTION

A D-type latch circuit triggering on level is a very popular circuit used for the realization of electronics circuits. It served from the very beginning of the electronic era for realizing all kinds of sophisticated circuits, and more particularly the commonplace static D flip-flop as well as frequency dividers.

With the increase in the operating frequency of electronic circuits, and particularly circuits used in the field of telecommunications, it is not rare to consider frequencies reaching values about 10 GHz.

Such frequencies are clearly an obstacle for the electronic circuit designer who can only use the known latches.

FIG. 1 illustrates a well-known circuit for a D flip-flop 10 which is realized with two D-latches 11 and 12 connected in a master-slave arrangement. Generally speaking, the practical realization of each D-latch 11 or 12 depends on the value of the operating frequency which will be considered.

An example for the realization of each latch 11 or 12, which is suitable for operating at a frequency value of several gigahertz, is illustrated in the circuit shown in FIG. 2. Such a latch is designated as a “static” latch, which means that this latch is capable of maintaining the stored information during an indeterminate period due to a memory cell, which does not depend on the operating frequency.

This latch is based on a differential structure comprising MOS transistors operating in saturated states with input and output signals having low magnitudes (e.g., between 200 and 400 millivolts).

With such a structure, each branch of the differential structures shows a current which is alternatively switched in accordance with the known Current Mode Logic designation, which is well known. The differential structure comprises MOS transistors 21 and 22, which are each associated with a corresponding resistive load 23 and 24. The memory cell comprises MOS transistors 27 and 28 and the two clock signals (true and inverse) are transmitted to the latch via transistors 25 and 26.

The low magnitude shown by such a static differential structure allows the use of high frequencies. However, it only provides low immunity to noise due to the involvement of signals of low magnitude and also due to the resistive loads 23 and 24 which generate non-negligible noise.

Furthermore, the use of such latches proves to be difficult in circuits which operate elsewhere with full magnitude signals (i.e., with signals fully varying between the ground voltage and the power supply voltage) that are classically used in CMOS circuits. Should designers wish to integrate such latches with CMOS circuits nevertheless, specific interfaces between CML latches and the remaining part of the CMOS circuits will have to be realized, and such interfaces are likely to limit the operating frequency of the circuits.

Additionally, this circuit entails a high power consumption, which is a significant drawback that prevents its use for battery powered circuits.

FIG. 3 illustrates another well-known realization of a D-latch which allows a high operating frequency. This dynamic D-latch is based on transistors 31 to 39 and the information stored within the capacitance junction of the MOS transistors has to be periodically refreshed.

This second known circuit has the advantages, with regard to the first known circuit, of reducing the phase noise as well as the power consumption and of utilizing full range signals. This dynamic D-latch, however, requires specific sizing of the internal parameters of the MOS transistors, and particularly the capacitance in order to fit the value of a desired operating frequency. A higher operating frequency will require a lower capacitance value in order to store the information. Therefore, such a dynamic D-latch can certainly not be a “wide-band” latch since it can only be operated in a relatively narrow range of frequencies.

Moreover, this known dynamic latch is not based on a differential and thus symmetrical structure operating with true and reverse input and output signals, but conversely on an unsymmetrical structure. Therefore, and this is certainly a significant drawback, the dynamic D-latch is fragile and particularly sensitive to the manufacturing process, which entails a significant amount of loss for the semiconductor manufacturer.

The dynamic structure is known as being sensitive to the variations in the manufacturing process and also to the mismatch of the components.

### SUMMARY OF THE INVENTION

It is an object of the present invention to provide a new structure for D-latch that is static, robust and operates at a wide band of frequencies, that uses wide magnitude input and output signals, so as to allow operation at a high frequency with a low phase noise.

Another object of the present invention is to provide a static D-latch structure that is easy to produce, perfectly differential and which can be operated at a high frequency.

It is a further object of the present invention to provide a latch which is capable of operating in a wide band of frequencies.

It is yet another object of the present invention to provide a D-latch which has reduced power consumption.

Still another object of the present invention is to provide a latch having limited phase noise because of the absence of load resistance.

Another object of the present invention is to provide a D-latch having a perfectly symmetric topology which is capable of handling complementary input and output signals. This significantly improves the phase noise since the differential structure eliminates the pair harmonics of the output signals.

It is still another object of the present invention to provide a robust D-latch which is less sensitive to the manufacturing process.

One embodiment of the present invention provides a D-type static latch circuit that includes a first circuit connected between a first reference potential and a second reference potential, a second circuit connected between the first and second reference potentials, and a third circuit. The first circuit includes a first, a second and a third transistor connected in series, and the second circuit includes a fourth, a fifth and a sixth transistor connected in series. The third circuit includes a seventh and an eighth transistor connected in series between the junction of the second and third transistors and the junction of the fifth and sixth transistors. The junction of the seventh and eighth transistors is connected to the first reference potential.

Data is transmitted via a first input to the gates of the third and seventh transistors, whereas the reverse data is transmitted via a second input to the gates of the sixth and eight transistors. A clock signal is transmitted to the gates of the second and fifth transistors which thus operate as a switch that selectively allows the data to pass to the upper part of the latch which is formed by the first and fourth transistors. The latch circuit generates an output signal at the junction of the first and second transistors, which is also connected to the gate of the fourth transistor. Similarly, a counterpart reverse output signal is generated at the junction of the fourth and fifth transistors, which is also connected to the gate of the first transistor.

Thus, there is provided a simple D-type static latch circuit formed by the eight MOS type transistors that does not require the use of a load resistor that might introduce a significant amount of phase noise. Further, this latch circuit can be operated at a very high frequency, since the clock signal is supplied to the second and fourth transistors that operate at a very high speed.

In one embodiment, the supply voltage is positive, and the first, fourth, seventh and eighth transistors are PMOS type transistors while the second, third, fifth and sixth transistors are of an opposite type (i.e., NMOS transistors).

Alternatively, in another embodiment the supply voltage is negative, and the first, second, seventh and eighth transistors are NMOS type transistors while the second, third, fifth and sixth transistors are PMOS type transistors.

In some embodiments, the first, second, third, fourth, fifth, sixth seventh and eighth transistors are substantially the same size so as to allow a perfectly symmetrical topology in both the vertical and horizontal directions.

The D-type static latch circuit can be used to realize many circuits, including a high speed serial link, a D-type flip-flop, a frequency divider that operates at a high speed, and a circuit generating four signals in perfect quadrature (0, 90, 180 and 270 degrees).

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 illustrates the structure of a D-latch that reacts on edges (i.e., a D flip-flop).

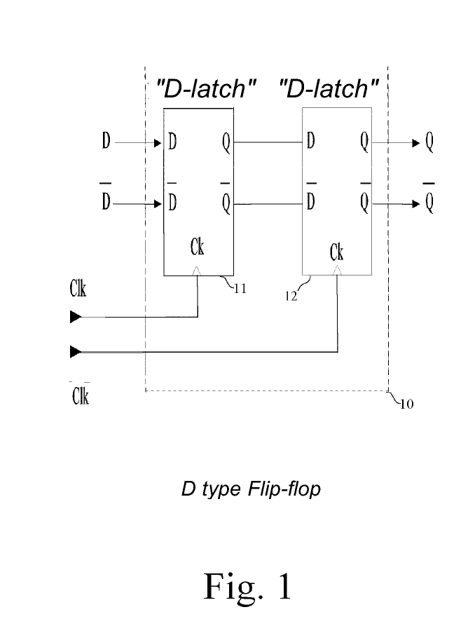

FIG. 2 illustrates a first well known structure for a static D-latch of the type Current Mode Logic (CML) for operating at a high frequency.

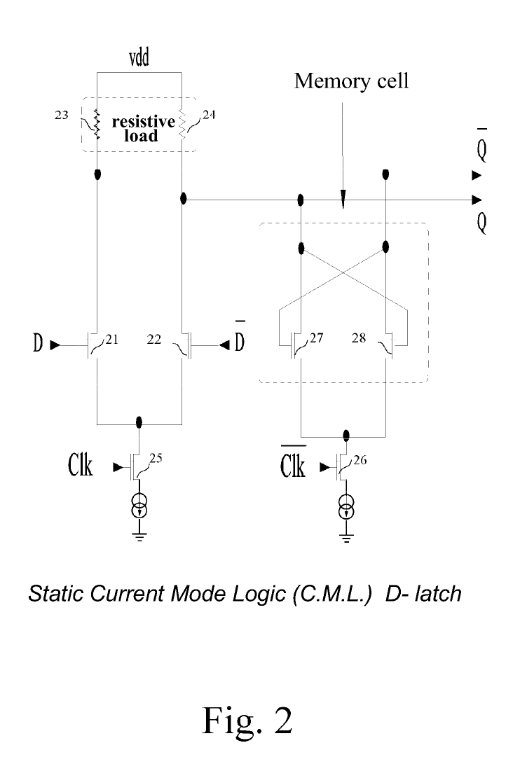

FIG. 3 illustrates a second well known structure of a dynamic CMOS latch.

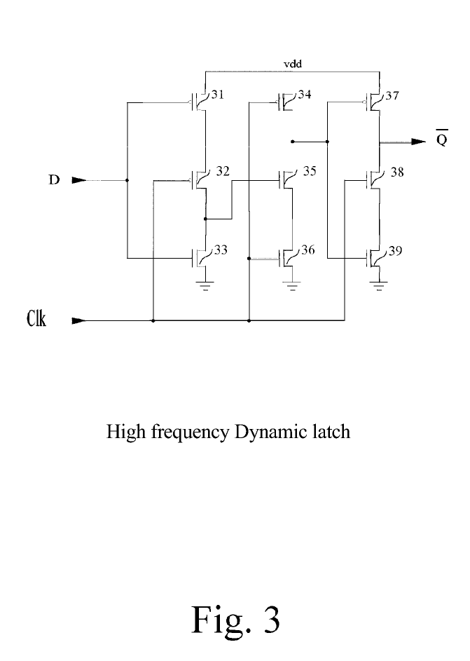

FIG. 4 illustrates a CMOS D-latch that is static and operates at high frequency in accordance with one embodiment of the present invention.

FIG. 5 illustrates a frequency division circuit that includes two elementary D-latches reacting on level.

FIG. 6 illustrates a generator of signals in quadrature that includes elementary D-latches.

### DETAILED DESCRIPTION OF PREFERRED EMBODIMENTS

Preferred embodiments of the present invention will be described in detail hereinbelow with reference to the attached drawings.

Preferred embodiments of the present invention provide a D-latch which is adapted to the use of a high operating frequency and which further reduces the phase noise.

There will be particularly described below an example of circuits which use a Vdd power supply voltage that is positive. However, the invention is not so limited. One of ordinary skill in the art can easily implement the corresponding dual structure based on a negative Vdd supply voltage, through transistors of opposite polarity than those used in the figures.

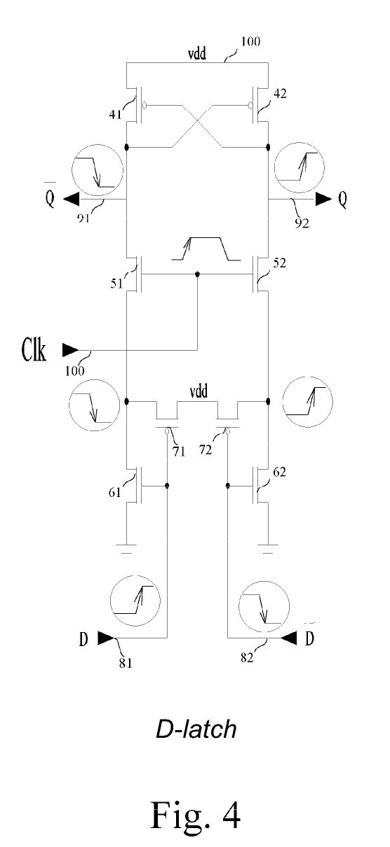

FIG. 4 illustrates a CMOS D-latch in accordance with one embodiment of the present invention. The D-latch of FIG. 4 is based on a structure that is perfectly symmetrical, which comprises two parallel branches that are connected between a first reference potential (which is assumed to be the power supply voltage Vdd) and a second reference potential (which is ground).

The first branch includes, in series, a first MOS type transistor 41, a second MOS transistor 51 and a third MOS transistor 61, while the second branch comprises, in series, a fourth MOS transistor 42, a fifth MOS transistor 52 and a sixth MOS transistor 62.

A seventh MOS transistor 71 and an eight MOS transistor 72 of the same type are connected in series between the junction of the second transistor 51 and the third transistor 61 and the junction of the fifth transistor 52 and the sixth transistor 62. Moreover, the junction of the seventh and eighth MOS transistors 71 and 72 is connected to the first reference potential Vdd.

The first, fourth, seventh and eighth MOS transistors 41, 42, 71 and 72 are of the same type which is opposed to the type of the transistors 51, 52, 61 and 62.

In the embodiment shown in FIG. 4, which is only an example and not meant to be limitative, the Vdd voltage is assumed to be positive and the transistors 41, 42, 71 and 72 are PMOS transistors, while transistors 51, 52, 61 and 62 are NMOS type transistors.

Data D is transmitted, via a terminal 81, to the gate of transistors 61 and 71 and, conversely, the reverse value of data D is introduced, as shown in the drawings, to the gates of transistors 62 and 72.

The CLK clock signal, which is received in the latch via a terminal 100, is supplied to the gate of the second transistor 51 and also to the gate of the fifth transistor 52, which thus operate as switches.

On the other hand, the junction between transistor 41 and transistor 51 is connected to the gate of transistor 42, and the junction between transistor 42 and transistor 52 is connected to the gate of transistor 41.

The D-latch also comprises a first output 92 generating the Q value, with the first output being connected to the junction of transistors 42 and 52 and also to the gate of transistor 41.

Similarly, the latch comprises a second complementary output 91 which generates the inverse value Q, and which is connected to the junction of transistors 41 and 51 and to the gate of transistor 42.

The D-latch of this embodiment of the present invention operates as follows.

Assuming that the D data (transmitted to the input 81) is a logical “1” and conversely that the reverse data D (transmitted to input 82) is a logical “0”, then due to the presence of PMOS transistors 71 and 72, those two values are introduced with gain respectively to the common terminal of transistors 51 and 61 (i.e., the source of transistor 51 and the drain of transistor 61) on one hand, and to the common terminal of transistor 52 and 62 on the other hand.

The values “1” and “0” that are forwarded to the terminals 81 and 82 are represented in FIG. 4 with a rising and a falling edge, respectively.

Those respectively rising and falling edges result, with some amplification, in falling edges and rising edges on the drains of transistors 61 and 62. Indeed, the amplification of the falling edge on the drain of the NMOS transistor 61 results from the existence of that transistor, while the amplification of the rising edge on the drain of transistor 62 comes from the presence of PMOS transistor 72. The symmetry of the circuit further results in the simultaneous transmission of the edges at the level of the source terminal of NMOS transistors 51 and 52.

Therefore, two very stable levels (respectively a logical “0” and a logical “1”) are transmitted to the switches composed of transistors 51 and 52, and on the occurrence of the rising edge of the clock signal presented on terminal 100, eventually appear on the drains of transistors 41 and 42.

Those levels are also transmitted to the gates of transistors 41 and 42, and the information is thus retained in the memory cell even when the clock signal switches back to a low level.

There is simplicity in this circuit which realizes a static D-latch, it is perfectly symmetrical and which, because of the lack of any load resistor, it shows a low level of noise.

The exemplary circuit which has been described has a Vdd voltage which is positive with respect to the reference voltage (ground). One of ordinary skill in the art can easily adapt these teachings of the present invention in order to realize a dual circuit having a Vdd voltage that is negative with respect to ground. In such a case, the circuit of FIG. 4 is still applicable but the transistors 41, 42, 71 and 72 are of an NMOS type while transistors 51, 61, 52 and 62 are of a PMOS type.

The D-latch which has been described can be operated at a very high frequency level. For example, the D-latch permits a high speed serial link to be manufactured, operating at a frequency of 10 GHz, while significantly reducing the amount of the phase noise. Experimental results have shown that the noise has been reduced to an amount of 147 dB/Hz at a frequency value of 1 MHz. Thus, the D-latch in accordance with this embodiment of the present invention significantly improves the immunity with respect to the noise, and further reduces the power consumption.

The D-latch which was described can serve to realize a great number of circuits and combinations, such as a D-type flip-flop.

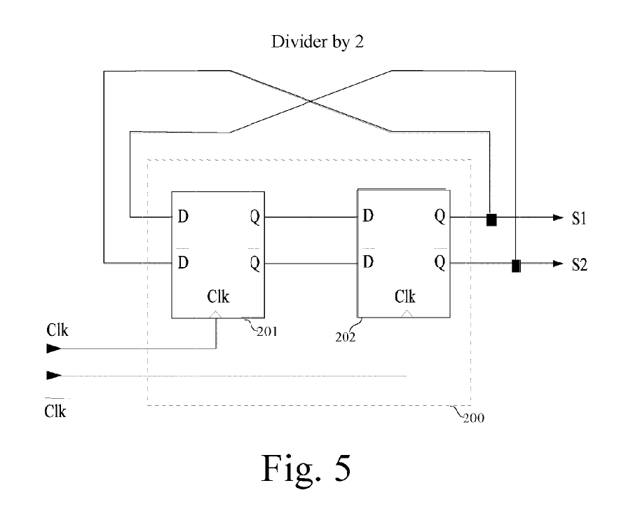

As shown in FIG. 5, the D-latch of the present invention can be used in order to realize a frequency divider 200, which includes two of the elementary latches 201 and 202 described above, that can be operated at a high frequency (e.g., 10 GHz).

In addition, the D-latch of the present invention has a remarkable advantage in that the PMOS type transistors do not have to switch high values of currents and, therefore, they can be sized at the same level as the NMOS transistors. One can thus very easily design a semiconductor topology which shows perfect symmetry, in both a vertical and a horizontal direction, with transistors being perfectly aligned.

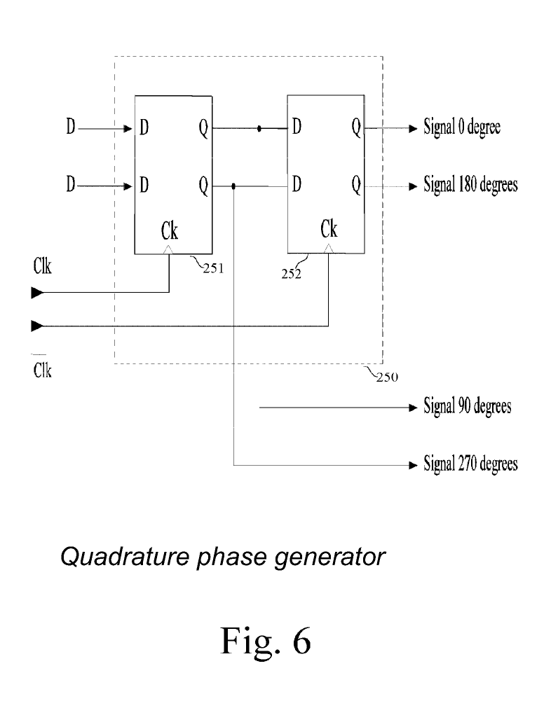

This contributes to the robustness of the latch, and particularly, if the latch is used for the realization of a phase quadrature circuit, as shown in FIG. 6, it was noticed that this circuit is particularly robust and shows low sensitivity to the phase errors which might be introduced at the inputs of the circuits. The output terminals 0°, 90°, 180° and 270° provide signals which remain perfectly in quadrature even when there is jitter at the inputs.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A D-type static latch circuit comprising:
a first circuit connected between a first reference potential and a second reference potential, the first circuit comprising a first transistor, a second transistor and a third transistor connected in series;
a second circuit connected between the first reference potential and the second reference potential, the second circuit comprising a fourth transistor, a fifth transistor and a sixth transistor connected in series;
a third circuit comprising a seventh transistor and a eighth transistor connected in series between a junction of the second transistor and the third transistor and a junction of the fifth transistor and the sixth transistor, a junction of the seventh transistor and the eighth transistor being connected to the first reference potential;
a first input for receiving data, the first input being connected to the gate of the third transistor and the gate of the seventh transistor;
a second input for receiving an inverse of the data, the second input being connected to the gate of the sixth transistor and the gate of the eighth transistor;
a third input for receiving a clock signal, the third input being connected to the gate of the second transistor and the gate of the fifth transistor;
a first output connected to a junction of the first transistor and the second transistor, the first output also being connected to the gate of the fourth transistor; and
a second output connected to a junction of the fourth transistor and the fifth transistor, the second output also being connected to the gate of the first transistor.

2. The D-type static latch circuit according to claim 1,
wherein the first reference potential is positive with respect to the second reference potential,
the first, fourth, seventh and eighth transistors are PMOS type transistors, and
the second, third, fifth and sixth transistors are NMOS type transistors.

3. The D-type static latch circuit according to claim 1,
wherein the first reference potential is negative with respect to the second reference potential,
the first, fourth, seventh and eighth transistors are NMOS type transistors, and
the second, third, fifth and sixth transistors are PMOS type transistors.

4. The D-type static latch circuit according to claim 1, wherein the first, second, third, fourth, fifth, sixth, seventh, and eighth transistors are substantially the same size.

5. A serial link capable of operating at a high frequency, the serial link comprising at least one D-type static latch circuit according to claim 1.

6. A D-type flip-flop comprising at least one D-type static latch circuit, the D-type static latch circuit comprising:
a first circuit connected between a first reference potential and a second reference potential, the first circuit comprising a first transistor, a second transistor and a third transistor connected in series;
a second circuit connected between the first reference potential and the second reference potential, the second circuit comprising a fourth transistor, a fifth transistor and a sixth transistor connected in series;
a third circuit comprising a seventh transistor and a eighth transistor connected in series between a junction of the second transistor and the third transistor and a junction of the fifth transistor and the sixth transistor, a junction of the seventh transistor and the eighth transistor being connected to the first reference potential;
a first input for receiving data, the first input being connected to the gate of the third transistor and the gate of the seventh transistor;
a second input for receiving an inverse of the data, the second input being connected to the gate of the sixth transistor and the gate of the eighth transistor;
a third input for receiving a clock signal, the third input being connected to the gate of the second transistor and the gate of the fifth transistor;
a first output connected to a junction of the first transistor and the second transistor, the first output also being connected to the gate of the fourth transistor; and
a second output connected to a junction of the fourth transistor and the fifth transistor, the second output also being connected to the gate of the first transistor.

7. The D-type flip-flop according to claim 6,
wherein the first reference potential is positive with respect to the second reference potential,
the first, fourth, seventh and eighth transistors are PMOS type transistors, and
the second, third, fifth and sixth transistors are NMOS type transistors.

8. The D-type flip-flop according to claim 6,
wherein the first reference potential is negative with respect to the second reference potential,
the first, fourth, seventh and eighth transistors are NMOS type transistors, and
the second, third, fifth and sixth transistors are PMOS type transistors.

9. The D-type flip-flop according to claim 6, wherein the first, second, third, fourth, fifth, sixth, seventh, and eighth transistors are substantially the same size.

10. A frequency division circuit comprising a cascade of at least two D-type static latch circuits, at least one of the D-type static latch circuits comprising:
a first circuit connected between a first reference potential and a second reference potential, the first circuit comprising a first transistor, a second transistor and a third transistor connected in series;
a second circuit connected between the first reference potential and the second reference potential, the second circuit comprising a fourth transistor, a fifth transistor and a sixth transistor connected in series;
a third circuit comprising a seventh transistor and a eighth transistor connected in series between a junction of the second transistor and the third transistor and a junction of the fifth transistor and the sixth transistor, a junction of the seventh transistor and the eighth transistor being connected to the first reference potential;
a first input for receiving data, the first input being connected to the gate of the third transistor and the gate of the seventh transistor;
a second input for receiving an inverse of the data, the second input being connected to the gate of the sixth transistor and the gate of the eighth transistor;
a third input for receiving a clock signal, the third input being connected to the gate of the second transistor and the gate of the fifth transistor;
a first output connected to a junction of the first transistor and the second transistor, the first output also being connected to the gate of the fourth transistor; and
a second output connected to a junction of the fourth transistor and the fifth transistor, the second output also being connected to the gate of the first transistor.

11. The frequency division circuit according to claim 10,
wherein the first reference potential is positive with respect to the second reference potential,
the first, fourth, seventh and eighth transistors are PMOS type transistors, and
the second, third, fifth and sixth transistors are NMOS type transistors.

12. The frequency division circuit according to claim 10,
wherein the first reference potential is negative with respect to the second reference potential,
the first, fourth, seventh and eighth transistors are NMOS type transistors, and
the second, third, fifth and sixth transistors are PMOS type transistors.

13. The frequency division circuit according to claim 10, wherein the first, second, third, fourth, fifth, sixth, seventh, and eighth transistors are substantially the same size.

14. The frequency division circuit according to claim 10, wherein the at least two D-type static latch circuits of the frequency division circuit are two D-type static latch circuits, with the outputs of the first D-type static latch circuit being coupled to the inputs of the second D-type static latch circuit and the outputs of the second D-type static latch circuit being cross-coupled to the inputs of the first D-type static latch circuit.

15. A phase quadrature circuit for generating four signals in quadrature, the phase quadrature circuit including two D-type static latch circuits, at least one of the D-type static latch circuits comprising:
a first circuit connected between a first reference potential and a second reference potential, the first circuit comprising a first transistor, a second transistor and a third transistor connected in series;
a second circuit connected between the first reference potential and the second reference potential, the second circuit comprising a fourth transistor, a fifth transistor and a sixth transistor connected in series;
a third circuit comprising a seventh transistor and a eighth transistor connected in series between a junction of the second transistor and the third transistor and a junction of the fifth transistor and the sixth transistor, a junction of the seventh transistor and the eighth transistor being connected to the first reference potential;
a first input for receiving data, the first input being connected to the gate of the third transistor and the gate of the seventh transistor;
a second input for receiving an inverse of the data, the second input being connected to the gate of the sixth transistor and the gate of the eighth transistor;
a third input for receiving a clock signal, the third input being connected to the gate of the second transistor and the gate of the fifth transistor;
a first output connected to a junction of the first transistor and the second transistor, the first output also being connected to the gate of the fourth transistor; and
a second output connected to a junction of the fourth transistor and the fifth transistor, the second output also being connected to the gate of the first transistor.

16. The phase quadrature circuit according to claim 15,
wherein the first reference potential is positive with respect to the second reference potential,
the first, fourth, seventh and eighth transistors are PMOS type transistors, and
the second, third, fifth and sixth transistors are NMOS type transistors.

17. The phase quadrature circuit according to claim 15,
wherein the first reference potential is negative with respect to the second reference potential,
the first, fourth, seventh and eighth transistors are NMOS type transistors, and
the second, third, fifth and sixth transistors are PMOS type transistors.

18. The phase quadrature circuit according to claim 15, wherein the first, second, third, fourth, fifth, sixth, seventh, and eighth transistors are substantially the same size.

19. The phase quadrature circuit according to claim 15,
wherein the outputs of the first D-type static latch circuit are coupled to the inputs of the second D-type static latch circuit, and
the outputs of the first and second latch circuits provide the four signals in quadrature.
